(19) United States
(12) Patent Application Publication
(10) Pub. No.: US 2008/0281549 A1
(43) Pub. Date: Nov. 13, 2008

(54) Test Apparatus for Control Unit, Pattern Signal Creating Apparatus, and Test Program Generating Apparatus

(75) Inventors: Masato Ishio, Hyogo (JP); Shigeyuki Hisai, Hyogo (JP); Taketomo Amie, Hyogo (JP); Koji Uchihashi, Hyogo (JP)

Correspondence Address: FOGG & POWERS LLC, 10 SOUTH FIFTH STREET, SUITE 1000, MINNEAPOLIS, MN, 55402, US

(73) Assignee: Fujitsu Ten Limited, Kobe-shi (JP)

(21) Appl. No.: 10/596,118

(22) PCT Filed: Nov. 26, 2004
(86) PCT No.: PCT/JP04/17970

§ 371 Date: May 31, 2006

(30) Foreign Application Priority Data
Dec. 1, 2003 (JP) 2003-402159

(51) Int. Cl. G01R 31/3183

(52) U.S. Cl. 702/124

(57) ABSTRACT

An apparatus for assisting the creation of a test program, to be run on a simulator that automatically tests an electronic unit, to thereby reduce the number of preparatory steps and enhance the reliability of the automatic testing. The apparatus is a test apparatus including: a simulating unit for simulating a target to be controlled by a control unit; and a testing unit for testing the operation of the control unit based on a relationship between a pattern signal input to the control unit and an output signal output from the simulating unit in response to the pattern signal, wherein the testing unit tests the operation of the control unit at predetermined timing and, if a decision is not obtained that the control unit is operating properly, retries the decision a predetermined number of times.

### TECHNICAL FIELD

The present invention relates to an apparatus (a test apparatus for a control unit, a pattern signal creating apparatus, and a test program generating apparatus) for assisting the creation of a test program to be run on a simulator that automatically performs a test by simulating the operating environment of an electronic unit.

### BACKGROUND ART

To test and evaluate an electronic unit such as an electronic control unit (ECU) mounted in a vehicle, a simulator is used that automatically performs the test by simulating the operating environment of the electronic unit. Test programs for operating such simulators are prepared by manually creating test patterns, decision logic, etc. based on manually prepared specifications.

Since the test patterns, decision logic, etc. are manually created when preparing the test program as described above, there arise a problem in terms of the number of steps involved and the reliability. The problem is magnified, in particular, when a person other than the person who prepared the test specification creates the test patterns, decision logic, etc.

### DISCLOSURE OF THE INVENTION

The present invention has been devised in view of the above problem, and an object of the invention is to provide an apparatus for assisting the creation of a test program to be run on a simulator that automatically tests an electronic unit, and thereby to reduce the number of preparatory steps and enhance the reliability of the automatic testing.

To achieve the above object, according to the present invention, there is provided a test apparatus for a control unit, comprising: simulating means for simulating a target to be controlled by the control unit; and testing means for testing the operation of the control unit based on a relationship between a pattern signal input to the control unit and an output signal output from the simulating means in response to the pattern signal, wherein the testing means tests the operation of the control unit at a predetermined timing and, if a decision is not obtained that the control unit is operating properly, retries the decision a predetermined number of times.

According to the present invention, there is also provided a pattern signal creating apparatus for creating a pattern signal, comprising: first function processing means for creating the pattern signal based on a control interval at which to control a unit that uses the pattern signal created by the pattern signal creating apparatus; and second function processing means for creating the pattern signal based on an interval different from the control interval.

According to the present invention, preferably the second function processing means creates the pattern signal based on an interval of time that extends over a plurality of control intervals.

Also preferably, the second function processing means creates the pattern signal based on an interval equal to each of the control intervals.

According to the present invention, there is also provided a pattern signal creating apparatus for creating a pattern signal, comprising: means for creating a correlation pattern signal for which correlation information relative to a reference pattern signal is specified; and display means for displaying the reference pattern signal and the created correlation pattern signal on the same screen.

According to the present invention, there is also provided a pattern signal creating apparatus for creating a pattern signal, comprising: display means for displaying, when there exists a correlation pattern signal for which correlation information relative to a reference pattern signal is specified, the reference signal and the correlation pattern signal on the same screen; and pattern signal interlinking changing means for changing the correlation pattern signal in interlinking fashion as the reference pattern signal changes, wherein when the reference pattern signal is edited, the display means redisplays the correlation pattern signal changed by the pattern signal interlinking changing means along with the edited reference pattern signal.

According to the present invention, there is also provided a test program creating apparatus for creating a test program for testing a diagnostic function by causing a control unit to output data, comprising: means for displaying the pattern signal to be processed in the control unit onto a screen; and means for enabling a setting to be made for the testing of the diagnostic function with the pattern signal displayed on the screen.

According to the present invention, the setting for the testing of the diagnostic function involves setting data output request information to be transmitted to the control unit and also setting a condition, based on which to determine whether the diagnostic function is working properly or not, when the data output request information is transmitted to the control unit.

According to the present invention, there is also provided a test program creating apparatus for creating a test program, comprising: a child project which contains a pattern signal to be input to a control unit and a condition for effecting a transition from the pattern signal to another pattern signal; a parent project which contains the child project and a condition for effecting a transition from the child project to another child project; display means for simultaneously displaying an edit screen for the child project and an edit screen for the parent project; first editing means for enabling contents of the child project to be edited by displaying the contents on the edit screen for the child project when the child project is selected from the edit screen displayed for the parent project on the display means; and second editing means for enabling contents of the child project to be edited by displaying setup information relating thereto on a new edit screen when the contents of the child project are selected from the edit screen displayed for the child project on the display means.

According to the present invention, there is also provided a test apparatus for a control unit, comprising: testing means for testing the operation of the control unit based on a relationship between a pattern signal input to the control unit and an output signal output in response to the pattern signal from a target being controlled by the control unit; and means for causing the testing means during execution of the pattern signal to switch to the execution of another pattern signal when a pattern signal transition condition for making a transition to the execution of that other signal holds.

According to the present invention, the creation of the test patterns, etc. is facilitated, the number of preparatory steps involved is reduced, and the reliability of the created test program is enhanced.

### BRIEF DESCRIPTION OF THE DRAWINGS

FIG. 1 is a diagram showing one configuration example of an electronic unit automatic test system containing an electronic unit automatic test program creation assisting apparatus according to the present invention.

FIG. 2 is a flowchart illustrating a procedure for a decision retry setting process performed by the assisting apparatus.

FIG. 3 is a flowchart illustrating a procedure for a retry decision process generated in the decision retry setting process for an 8-ms updating counter and performed by a simulator.

FIG. 4 is a diagram showing how the decision on the 8-ms updating counter is made in the retry decision process of FIG. 3.

FIGS. 5A, 5B, and 5C are diagrams showing examples of sine-wave signals generated by the assisting apparatus.

FIG. 6 is a flowchart illustrating a procedure for a sine signal creation process performed by the assisting apparatus.

FIG. 7 is a diagram showing an example of a screen display for defining correlated signals.

FIG. 8 is a diagram showing an example of a time chart of the correlated signals.

FIG. 9 is a flowchart illustrating a procedure for a correlated signal creation process performed by the assisting apparatus.

FIG. 10 is a flowchart illustrating a procedure for a signal pattern creation process performed by the assisting apparatus.

FIG. 11 is a diagram showing an example of a communication data setting screen.

FIG. 12 is a flowchart illustrating a procedure for a communication event signal creation process performed by the assisting apparatus.

FIG. 13 is a program illustrating a procedure for a communication function test process performed by the assisting apparatus.

FIG. 14 is a diagram showing an example of a functional configuration (software configuration) for implementing a test pattern state transition setting function.

FIG. 15 is a diagram showing an example of a state transition setting screen.

FIG. 16 is a diagram showing an example of a chart screen.

FIG. 17 is a diagram showing an example of a transition condition setting screen.

FIG. 18 is a flowchart (part 1) illustrating a procedure for a state transition setting process performed by the assisting apparatus.

FIG. 19 is a flowchart (part 2) illustrating the procedure for the state transition setting process performed by the assisting apparatus.

FIG. 20 is a flowchart illustrating a procedure for an automatic test process performed by the simulator.

### BEST MODE FOR CARRYING OUT THE INVENTION

An embodiment of the present invention will be described below with reference to the accompanying drawings.

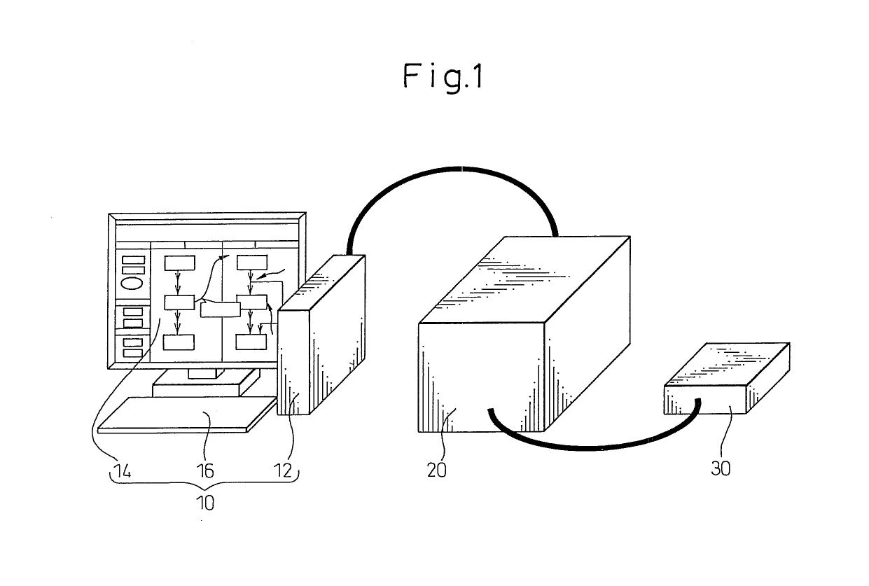

FIG. 1 is a diagram showing one configuration example of an electronic unit automatic test system containing an electronic unit automatic test program creation assisting apparatus 10 according to the present invention. As shown, the system comprises the electronic unit automatic test program creation assisting apparatus 10, a simulator 20, and an electronic unit 30.

The electronic unit 30 is the target for automatic testing, and is, in the present embodiment, an electronic control unit (ECU) to be mounted in a vehicle. The simulator 20 is a computer that performs the automatic testing by simulating the operating environment of the ECU 30. The automatic test program creation assisting apparatus (hereinafter referred to as the assisting apparatus) 10 is an apparatus for assisting the creation of a test program to be run on the simulator 20, and is implemented using an ordinary personal computer which comprises a computer main unit (containing a CPU, a storage device, etc.) 12, a display 14, a keyboard 16, etc.

Basically, the assisting apparatus 10 is used to enter a test specification for the ECU 30 based on input operations that the user performs on the screen, that is, by using a GUI (Graphical User Interface), and to generate a test pattern (including an input signal to the ECU 30 and decision logic for deciding whether the signal output from the ECU 30 in response to the input signal is correct or not) based on the test specification.

In the automatic test system of the configuration shown in FIG. 1, when automatically making a decision on a value in a RAM (Random Access Memory) within the ECU 30 at every execution interval of the simulator 20, an erroneous decision may occur because of a displacement occurring between the timing at which the ECU 30 updates the RAM value and the timing at which the simulator 20 samples the RAM value. To address this, the assisting apparatus 10 supports a decision retry function as one of the functions when generating the decision logic. The decision retry function allows the user to set the number of retries so that, if an NG decision is made once, the NG decision is not determined immediately, but the decision is retried the specified number of times, thereby aiming to prevent the occurrence of an erroneous decision.

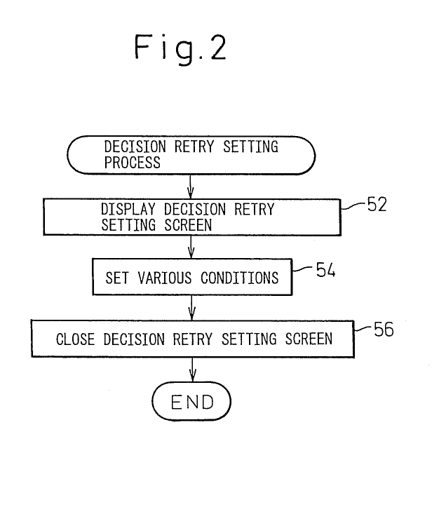

FIG. 2 is a flowchart illustrating a procedure for a decision retry setting process performed by the assisting apparatus 10. First, in step 52, a decision retry setting screen is displayed for setting the decision to be retried, the number of retries, and the retry interval time. Next, in step 54, processing is performed to set various conditions for retrying the decision. For example, the user can specify on the screen that the retry is to be set for the decision that is made on an 8-ms updating counter in the ECU 30, that the number of retries is 2, and that the retry interval time is 1 ms. Finally, in step 56, the decision retry setting screen is closed.

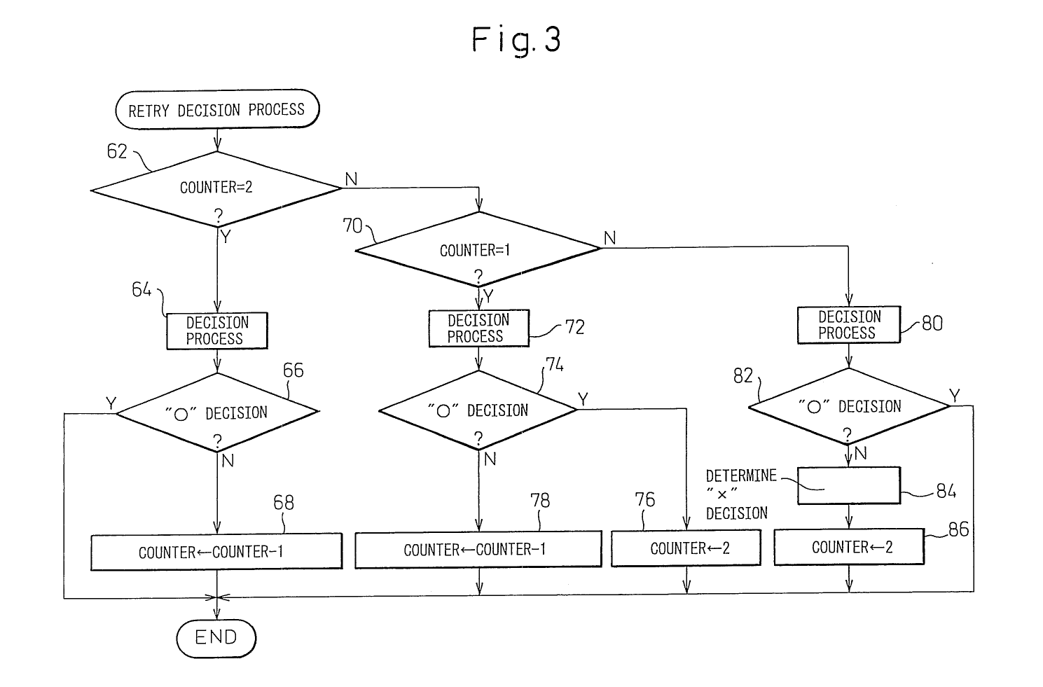

FIG. 3 is a flowchart illustrating a procedure for a retry decision process generated in the above decision retry setting process for the 8-ms updating counter and performed by the simulator 20. In this process, first it is determined in step 62 whether a retry counter for counting the number of retries is equal to 2 or not. The retry counter is initialized to 2 in an initialization process performed at every main interval. If the retry counter is equal to 2, the process proceeds to step 64 where a decision process (usual decision process) is performed to determine whether the 8-ms updating counter is updated correctly. In step 66, it is determined whether the decision is “O” (OK) and, if the decision is “O”, the routine is terminated; on the other hand, if the decision is “x” (NG), then in step 68 the retry counter is decremented, after which the routine is terminated.

If it is determined in step 62 that the retry counter is not equal to 2, the process proceeds to step 70 to determine whether the retry counter is equal to 1 or not. If the retry counter is equal to 1, the process proceeds to step 72 where a decision process (first retry decision process) is performed. In step 74, it is determined whether the decision is “O” and, if the decision is “O”, the retry counter is set back to 2 in step 76, after which the routine is terminated; on the other hand, if the decision is “x”, then in step 78 the retry counter is further decremented, after which the routine is terminated.

If it is determined in step 70 that the retry counter is not equal to 1, the process proceeds to step 80 where a decision process (second retry decision process) is performed. In step 82, it is determined whether the decision is “O” and, if the decision is “O”, the routine is terminated; on the other hand, if the decision is “x”, processing is performed in step 84 to determine the “x” decision, and the retry counter is set back to 2 in step 86, after which the routine is terminated.

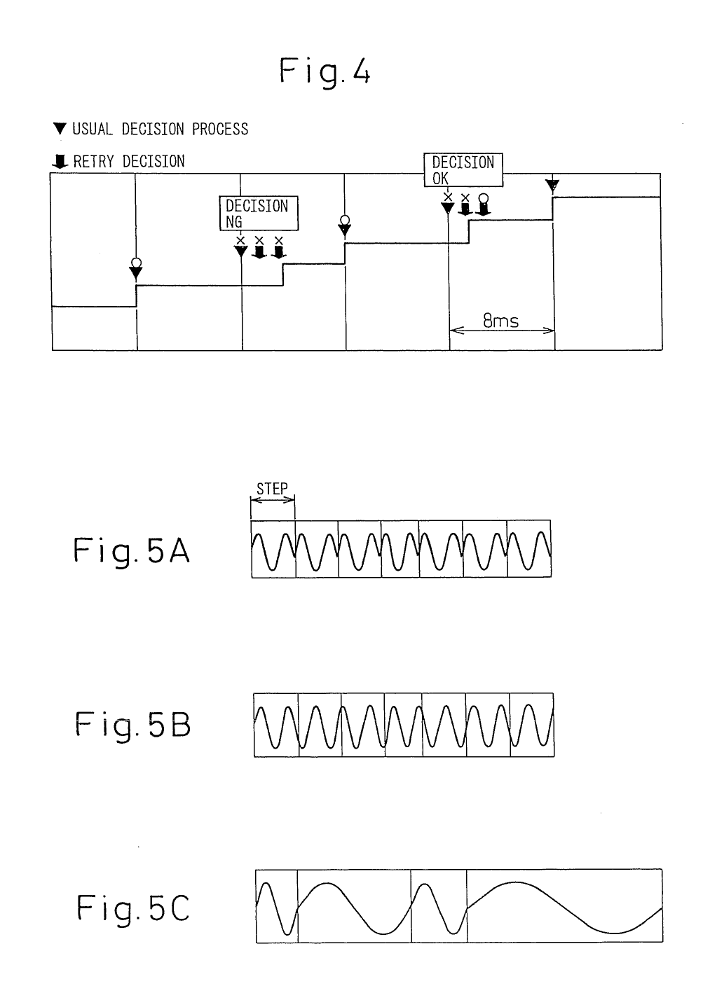

FIG. 4 shows how the decision on the 8-ms updating counter is made in the retry decision process of FIG. 3. As shown, if the NG decision is made once, the NG decision is not determined immediately, but the decision is retried the specified number of times (twice in the illustrated example). This decision retry function not only serves to prevent the occurrence of an erroneous decision but also serves to improve the function for setting a watched expression (an expression for determining whether the decision is correct or not) in the decision logic.

To assist the user to create a test pattern for the ECU 30, the assisting apparatus 10 is equipped with a function for preparing a pattern signal edit function, whose variable is the time, and for generating a pattern signal in accordance with the specified function. Here, in cases where the pattern signal can only be described using the time variable for each test step, there arises the problem that, if the pattern signal is described as extending over more than one step, a discontinuity occurs in the signal as it extends from one step to the next, and a desired pattern signal cannot be described. That is, when a sine signal y=sin(ω($T)) is described using, for example, the elapsed time $T within each step, a signal such as shown in FIG. 5A will result.

To address this, in the assisting apparatus 10, not only the variable representing the time within each step but also a variable representing the time extending over a plurality of steps is used so that a pattern signal extending over the plurality of steps can be arbitrarily set without discontinuities. For example, a sine signal y=sin(ω($SYSTEMTIME)) can be described using the elapsed time $SYSTEMTIME elapsed from the time of starting, to generate a signal such as shown in FIG. 5B.

Further, when describing a sine wave using the variable representing the time within each step, if the sine signal cannot be described by changing the period for each individual step, the desired Sin wave cannot be generated. In view of this, in the assisting apparatus 10, the description y=sin((2π/t)($T)) having a constant period is extended to support the description y=sin((2π/$STEP)($T)) that can set the period as desired using the variable $STEP, thereby enabling the period to be changed for each step as shown in FIG. 5C.

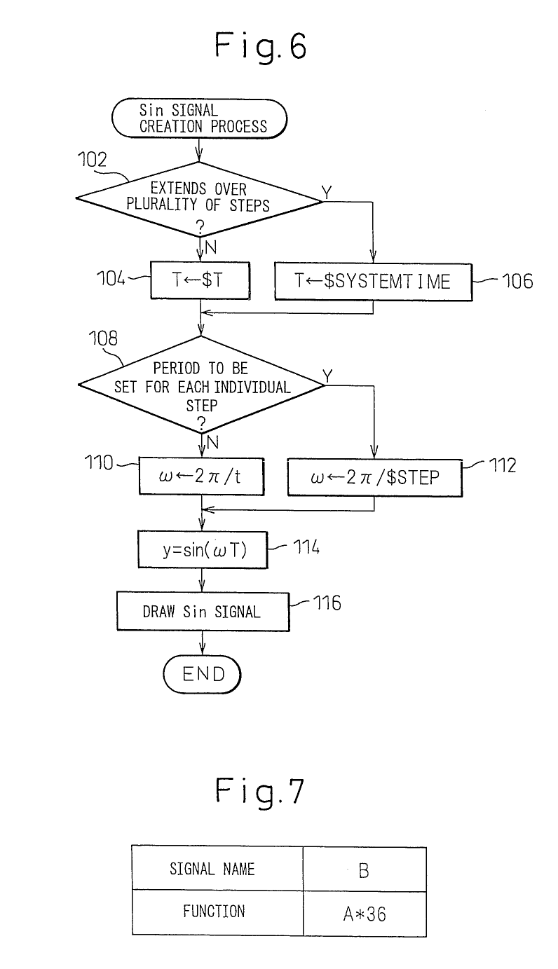

FIG. 6 is a flowchart illustrating a procedure for a Sin signal creation process performed by the assisting apparatus 10. First, in step 102, it is determined whether the input Sin function is a description extending over a plurality of steps. If it is not a description extending over a plurality of steps, the process proceeds to step 104 where an input $T is substituted for the variable T; on the other hand, if it extends over a plurality of steps, the process proceeds to step 106 where an input $SYSTEMTIME is substituted for the variable T.

Next, in step 108, it is determined whether the period is to be set for each individual step or not. If the period is not to be set for each individual step, the process proceeds to step 110 where the angular frequency ω is set to 2π/t; on the other hand, if the period is to be set for each individual step, the process proceeds to step 112 where the angular frequency ω is set to 2π/$STEP. Next, in step 114, the Sin signal y=sin(ωT) is created using T and ω obtained in the preceding step, and finally, in step 116, the Sin signal thus created is drawn on the screen. In this way, by extending the variable representing the time, it becomes possible to set the desired waveform by the Sin signal, thus enhancing the pattern signal edit function.

Here, when creating two or more pattern signals varying in relation to each other, if they are to be set separately, not only does the number of steps for creating the signals increase, but the number of steps for changing them also increases. In view of this, in the assisting apparatus 10, a signal that serves as a reference is specified in the case of two or more correlated signals, and an offset and a coefficient relative to the reference signal are set, thereby making it possible to create two or more pattern signals varying in relation to each other.

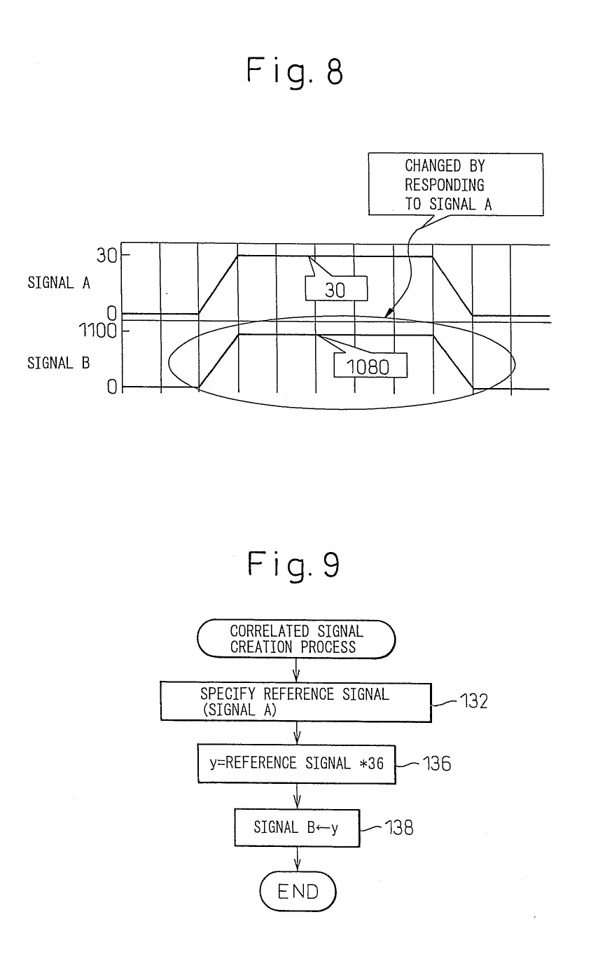

More specifically, when a signal B is defined as signal A*36 by using a function input function on a pattern signal edit screen as shown in FIG. 7, then as shown in FIG. 8 the signal B is automatically created by multiplying the signal A by 36 and, when a correction is made to the signal A, the signal B is also corrected automatically by responding to the correction.

FIG. 9 is a flowchart illustrating a procedure for the correlated signal creation process performed by the assisting apparatus 10. First, in step 132, the signal A is specified as the reference signal. Next, in step 134, y is obtained by calculating “reference signal*36” based on the specified functional equation. Finally, in step 136, the signal B is created by using the calculation result y. In this way, a plurality of correlated signals can be easily created, and the number of steps for changing the pattern signals can also be reduced.

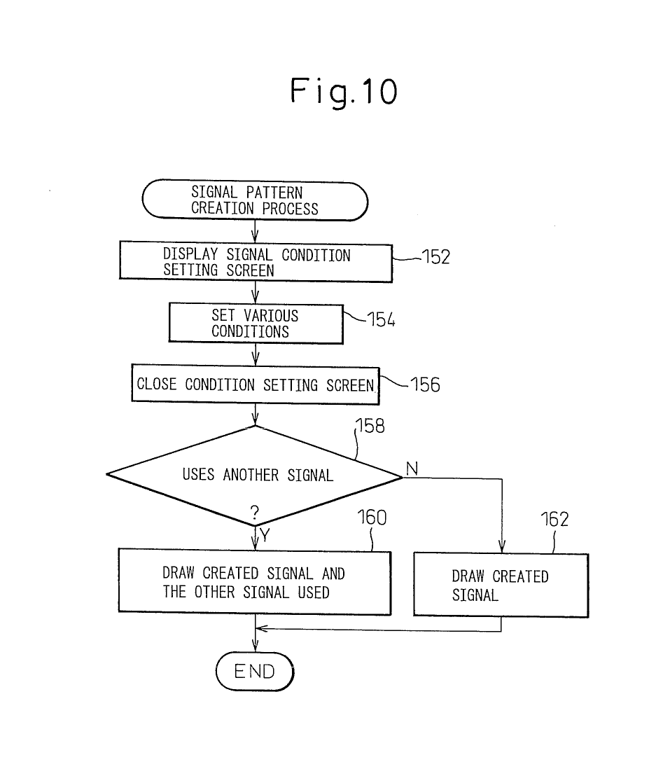

FIG. 10 is a flowchart illustrating a procedure for a signal pattern creation process performed by the assisting apparatus 10. First, in step 152, a screen for setting signal conditions is displayed. Next, in step 154, various conditions are set by entering data on the screen. In step 156, the condition setting screen is closed. Then, in step 158, it is determined whether the created signal uses another signal, that is, whether the signal is created using another signal as described above. If the signal is one created using another signal, the process proceeds to step 160 where the created signal and that other signal used are drawn simultaneously; on the other hand, if the signal is not one created using another signal, the process proceeds to step 162 where only the created signal is drawn. The signal pattern creation process is thus completed.

Generally, the ECU 30 is equipped with a diagnostic function. If communication data and decision values for testing the diagnostic function are to be set using different screens, the number of steps involved will increase. In view of this, the assisting apparatus 10 is equipped with a function for setting transmit data to be transmitted to the ECU 30 under test, its transmit timing, and the theoretical value of the data to be received from the ECU 30 in response to the transmitted data, and thereby automatically transmitting the data to the ECU 30 and determining whether the data received from the ECU 30 is correct or not.

This function is a GUI function that makes the settings (transmit data, transmit timing, and received data) necessary for testing the diagnostic function while displaying the transmit data, the transmit timing, and the received data theoretical value on the same screen along with other input/output signal charts (voltage, switch, duty, etc.) of the ECU 30 so that the whole test specification can be viewed.

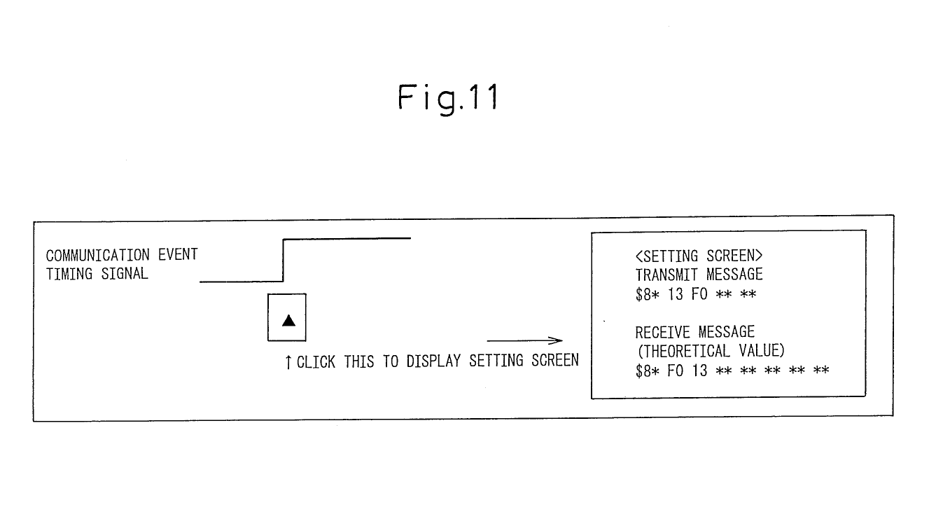

More specifically, as shown in FIG. 11, when an event mark (solid rectangular mark) set for a specific signal as a communication event timing signal is clicked on the signal pattern edit screen, a communication data setting screen window is displayed, allowing the user to set the transmit message and receive message (theoretical value) for that specific signal. The transmit timing is automatically set in accordance with the position of the event mark clicked.

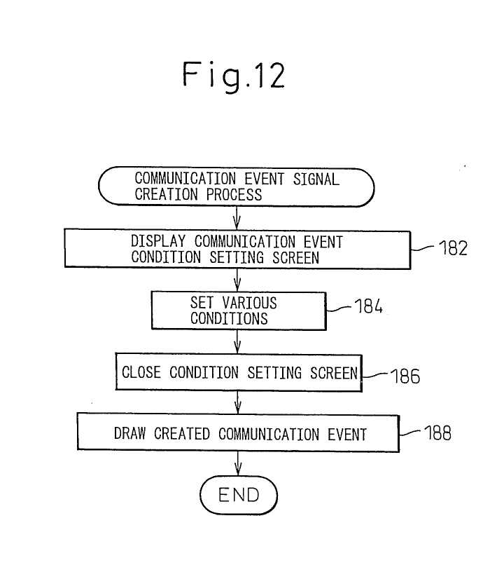

FIG. 12 is a flowchart illustrating a procedure for the communication event signal creation process performed by the assisting apparatus 10. First, in step 182, the communication event condition setting screen, such as that shown in FIG. 11, is displayed. Next, in step 184, various conditions (transmit message, transmit timing, and receive message theoretical value) are set by entering data through a GUI. In step 186, the condition setting screen is closed. Finally, in step 188, the created communication event is drawn; at the same time, the diagnostic function test program that can be run on the simulator 20 is created.

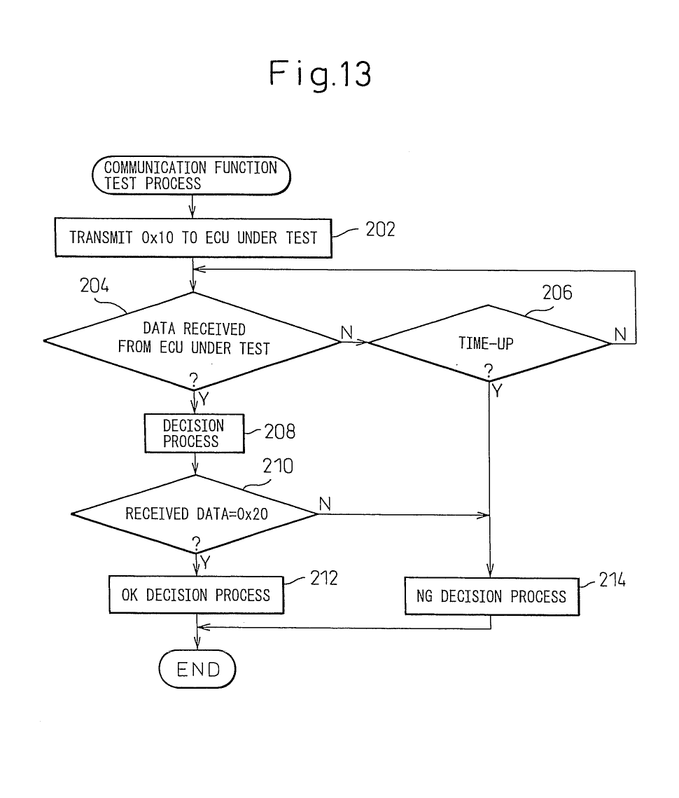

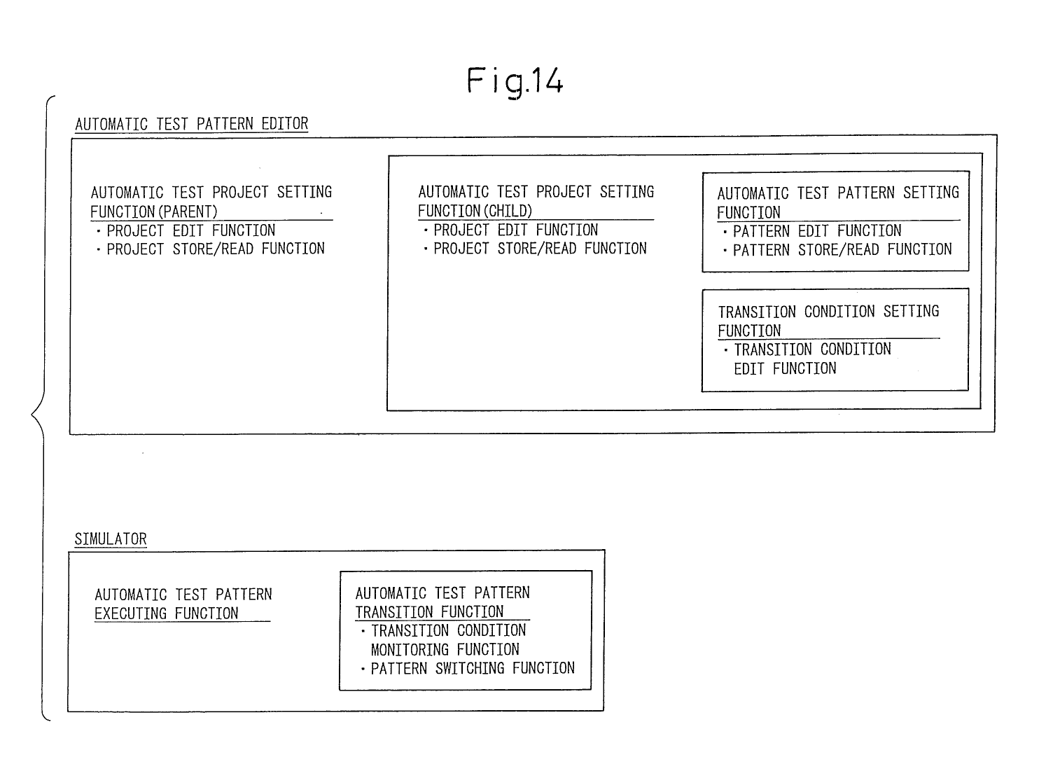

FIG. 13 is a flowchart illustrating a procedure for the diagnostic function test process performed by the assisting apparatus 10. This process transmits data 0x10 to the ECU 30 under test and verifies whether the data returned from the ECU 30 is data 0x20. First, in step 202, the data 0x10 is transmitted to the ECU under test. Next, in step 204, it is determined whether any data is received from the ECU under test. If data is not received, the process proceeds to step 206 to check whether a time-out has occurred; if not, the process returns to step 204.

When data is received from the ECU under test in step 204, a decision is made on the received data in step 208, and it is checked in step 210 to see whether the received data is 0x20 or not. If the received data matches the expected value 0x20, an OK decision process is performed in step 212; on the other hand, if the received data does not match the expected value, the process proceeds to step 214 where an NG decision process is performed. Further, when it is determined in step 206 that a time-out has occurred, the NG decision process in step 214 is likewise performed.

In this way, the communication test items can be designed on the same screen easily and reliably and, at the same time, the number of design steps for the diagnostic-related automatic test can be reduced.

When performing tests having similar purposes, it is preferable to store common test items in a single file so that they can be reused. In view of this, the assisting apparatus 10 is equipped with a test pattern state transition setting function to enable the common test items to be reused.

FIG. 14 is a diagram showing an example of a functional configuration (software configuration) for implementing the state transition setting function. An automatic test pattern editor incorporated in the assisting apparatus 10 has an automatic test project setting function (parent) which comprises a project edit function and a project store/read function. The automatic test project setting function (parent) contains an automatic test project setting function (child) which likewise comprises a project edit function and a project store/read function. The automatic test project setting function (child) contains an automatic test pattern setting function and a transition condition setting function. The automatic test pattern setting function comprises a pattern edit function and a pattern store/read function, and the transition condition setting function includes a transition condition edit function. On the other hand, the simulator is equipped with an automatic test pattern executing function, and the automatic test pattern executing function contains an automatic test pattern transition function which comprises a transition condition monitoring function and a pattern switching function.

Based on the above functional configuration, the state transition setting function implements a function for storing each designed test pattern in a single file (hereinafter referred to as the pattern file) and for reading out the stored pattern file and re-editing it and/or saving it under another name. Further, for a test pattern 1 designed by the automatic test pattern editor and a test pattern 2 set for a different purpose, the state transition setting function implements a function for constantly monitoring a separately set condition (hereinafter referred to as the pattern transition condition) during the execution of the test pattern 1 on the simulator and for effecting a transition to the execution of the test pattern 2 when the transition condition holds.

The state transition setting function further implements a function for enabling such a pattern transition condition to be set through a GUI and storing information concerning the combination of the test pattern 1, the test pattern 2, and the pattern transition condition in a file under an arbitrary project name (hereinafter referred to as the project file), and for reading out the stored project file and re-editing it and/or saving it under another name.

Furthermore, the state transition setting function implements a function for designing a plurality of such projects and setting, between the plurality of projects, a project transition condition similar to the pattern transition condition, thereby implementing the state transition between the projects in the simulation environment.

The state transition setting function has a hierarchical structure with the project transition condition setting section as a parent and the pattern transition condition setting section as a child, and displays the two sections simultaneously on the same screen, thereby implementing a GUI having a function that can set the two transition conditions simultaneously and edit the project/pattern combination setting.

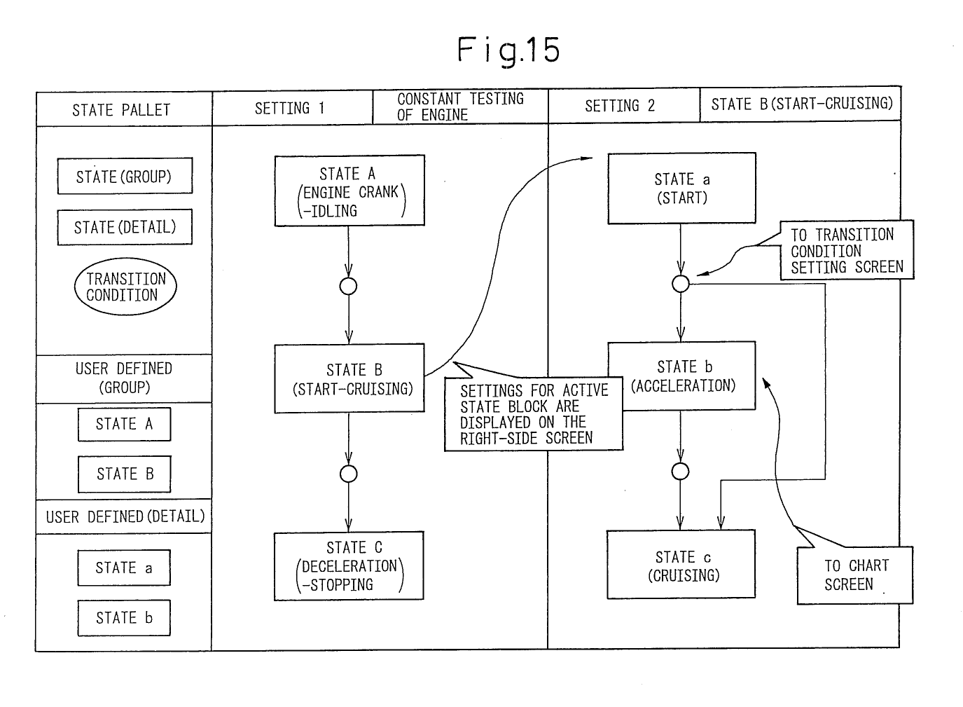

A specific example of the state transition setting screen is shown in FIG. 15. In the “SETTING 1” section in the left side of the screen, there are arranged a plurality of state blocks “STATE A”, “STATE B”, and “STATE C” as projects (each project-related state is referred to as the “group”). Nodes indicated by open circles (O) between the respective state (“group”) blocks “STATE A”, “STATE B”, and “STATE C” represent project transition conditions. With this “SETTING 1”, it becomes possible to edit the test program comprising a plurality of projects and project transition conditions.

On the other hand, in the “SETTING 2” section in the right side of the screen, there are arranged a plurality of state blocks “STATE a”, “STATE b”, and “STATE c” as test patterns constituting the “STATE B” which is the currently active state (“group”) block (each test-pattern-related state is referred to as the “detail”). Nodes indicated by open circles (O) between the respective state (“detail”) blocks “STATE a”, “STATE b”, and “STATE c” represent pattern transition conditions. With this “SETTING 2”, it becomes possible to edit the projects each comprising a plurality of test patterns and pattern transition conditions.

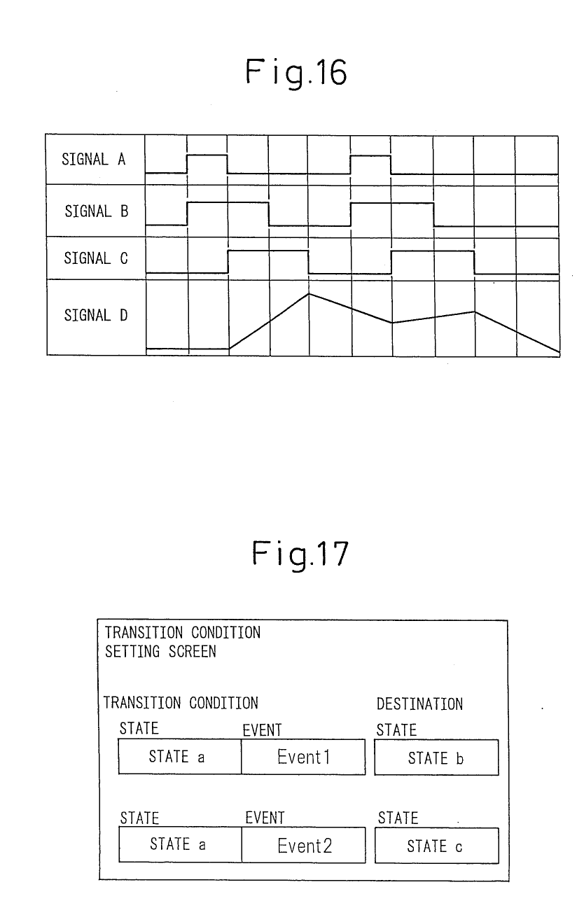

On the screen shown in FIG. 15, when the state (“detail”) block “STATE a”, for example, is double-clicked, a chart screen showing the test pattern signals relating to the “STATE a”, such as shown in FIG. 16, is displayed, allowing the user to edit the contents.

When the node indicated by the open circle (O) between the “STATE a” and the “STATE b” is doubled-clicked, a transition condition setting screen for that pattern transition condition, such as shown in FIG. 17, is displayed showing its contents. The transition condition setting screen in this example shows that when in “STATE a”, if “Event 1” occurs, a transition is made to “STATE b”, but if “Event 2” occurs, a transition is made to “STATE c”. This screen allows the user to set or change the pattern transition condition. The same applies for the project transition condition.

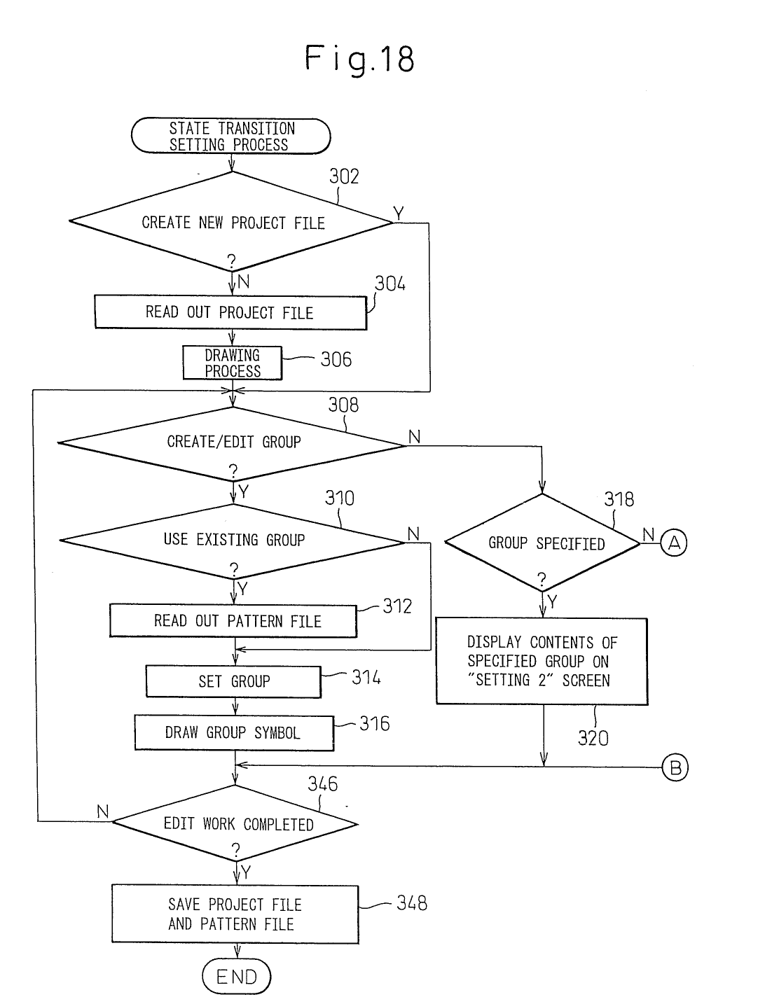

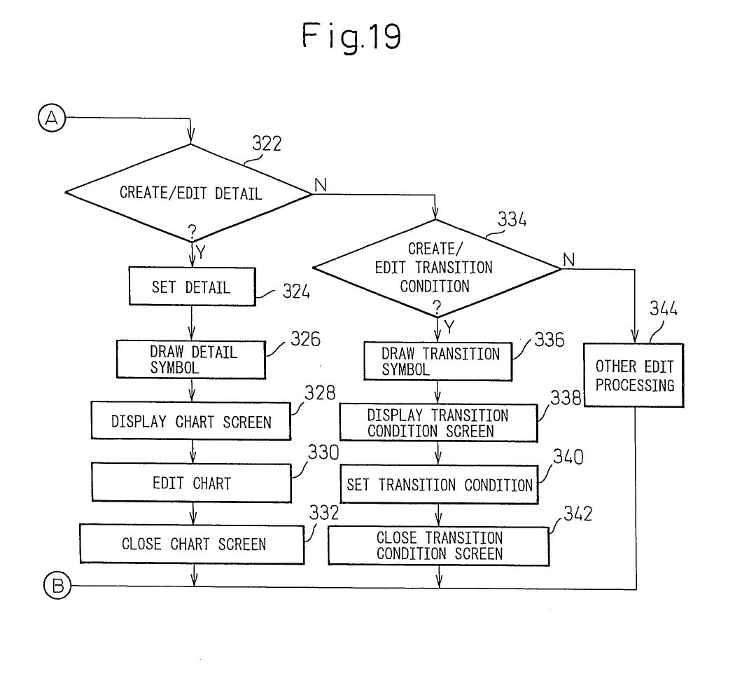

FIGS. 18 and 19 show a flowchart illustrating a procedure for the state transition setting process performed by the assisting apparatus 10. First, in step 302, it is determined whether a new project file is to be created; in the case of a new project file, the process proceeds to step 308. Otherwise, the process proceeds to step 304 to read out an existing project file and, after the screen is drawn in accordance with the project file, the process proceeds to step 308.

In step 308, it is determined whether a “group” is to be created/edited; if a “group” is to be created/edited, then in step 310 it is determined whether an existing “group” is to be used or not. Only when an existing “group” is to be used does the process proceeds to step 312 to read out the corresponding pattern file.

Next, in step 314, the “group” is set in accordance with the user input, and in step 316, the symbol representing the thus set “group” is drawn.

If it is determined in step 308 that a “group” is neither to be created nor to be edited, the process proceeds to step 318 where it is determined whether any “group” is specified or not. If any “group” is specified, the process proceeds to step 320 to display the contents of the specified “group” on the “SETTING 2” screen.

If it is determined in step 318 that no “group” is specified, the process proceeds to step 322 where it is determined whether a “detail” is to be created/edited. In the case of creating/editing a “detail”, the “detail” is set in step 324 in accordance with the user input, and the symbol representing the thus set “detail” is drawn in step 326. Next, the chart screen (FIG. 16) is displayed in step 328, and the chart is edited in step 330, after which the chart screen is closed in step 332.

If it is determined in step 322 that a “detail” is neither to be created nor to be edited, the process proceeds to step 334 where it is determined whether the “transition condition” is to be created/edited. In the case of creating/editing the “transition condition”, the “transition” symbol is drawn in step 336. Next, the “transition condition” setting screen (FIG. 17) is displayed in step 338, and the “transition condition” is set in step 340, after which the “transition condition” setting screen is closed in step 342.

If it is determined in step 334 that the “transition condition” is neither to be created nor to be edited, the process proceeds to step 344 where other edit processing is performed. After performing the step 316, 320, 332, 342, or 344, the process proceeds to step 346 to determine whether all edit work is completed. If not completed yet, the process loops back to step 308. On the other hand, if the edit work is completed, then, in step 348, the project file and the pattern file are saved and the routine is terminated.

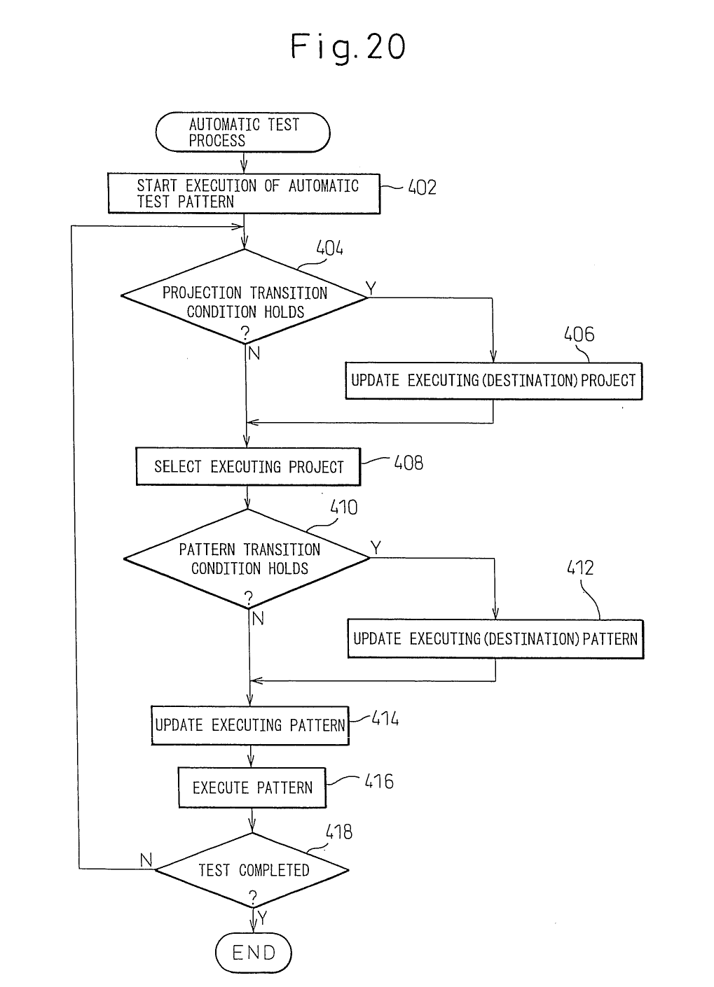

FIG. 20 is a flowchart illustrating a procedure for an automatic test process that the simulator 20 performs in accordance with the test program created by performing the above-described state transition setting process. First, when the execution of an automatic test pattern is started in step 402, it is determined in step 404 whether the project transition condition holds or not. If the project transition condition holds, the executing (destination) project is updated in step 406.

Next, in step 408, the executing project is selected. Then, it is determined in step 410 whether the pattern transition condition holds or not. If the pattern transition condition holds, the executing (destination) pattern is updated in step 412.

Then, in step 414, the executing pattern is selected, and in step 416, the selected pattern is executed. In step 418, it is determined whether the test is completed or not and, if not completed yet, the process loops back to step 404; on the other hand, if the test is completed, the automatic test process is terminated.

By thus storing the test patterns in the form of a library and implementing the pattern-to-pattern state transition function, the reuse rate of the test patterns increases. Further, by implementing the above setting function on one screen, the number of steps needed for designing the test patterns can be reduced.

What is claimed is:

1. A test apparatus for a control unit, comprising:
simulating means for simulating a target to be controlled by said control unit; and
testing means for testing the operation of said control unit based on a relationship between a pattern signal input to said control unit and an output signal output from said simulating means in response to said pattern signal, wherein
said testing means tests the operation of said control unit at predetermined timing and, if a decision is not obtained that said control unit is operating properly, retries said decision a predetermined number of times.

2. A pattern signal creating apparatus for creating a pattern signal, comprising:
first function processing means for creating said pattern signal based on a control interval at which to control a unit that uses said pattern signal created by said pattern signal creating apparatus; and
second function processing means for creating said pattern signal based on an interval different from said control interval.

3. A pattern signal creating apparatus as claimed in claim 2, wherein said second function processing means creates said pattern signal based on an interval of time that extends over a plurality of said control intervals.

4. A pattern signal creating apparatus as claimed in claim 3, wherein said second function processing means creates said pattern signal based on intervals equal to each of said control intervals.

5. A pattern signal creating apparatus for creating a pattern signal, comprising:
means for creating a correlation pattern signal for which correlation information relative to a reference pattern signal is specified; and
display means for displaying said reference pattern signal and said created correlation pattern signal on the same screen.

6. A pattern signal creating apparatus for creating a pattern signal, comprising:
display means for displaying, when there exists a correlation pattern signal for which correlation information relative to a reference pattern signal is specified, said reference signal and said correlation pattern signal on the same screen; and
pattern signal interlinking changing means for changing said correlation pattern signal in interlinking fashion as said reference pattern signal changes, wherein
when said reference pattern signal is edited, said display means redisplays said correlation pattern signal changed by said pattern signal interlinking changing means along with said edited reference pattern signal.

7. A test program creating apparatus for creating a test program for testing a diagnostic function by causing a control unit to output data, comprising:
means for displaying said pattern signal to be processed in said control unit onto a screen; and
means for enabling a setting to be made for said testing of said diagnostic function with said pattern signal displayed on said screen.

8. A test program creating apparatus as claimed in claim 7, wherein said setting for said testing of said diagnostic function involves setting data output request information to be transmitted to said control unit and also setting a condition based on which to determine whether said diagnostic function is working properly or not when said data output request information is transmitted to said control unit.

9. A test program creating apparatus for creating a test program, comprising:
a child project which contains a pattern signal to be input to a control unit and a condition for effecting a transition from said pattern signal to another pattern signal;
a parent project which contains said child project and a condition for effecting a transition from said child project to another child project;
display means for simultaneously displaying an edit screen for said child project and an edit screen for said parent project;
first editing means for enabling contents of said child project to be edited by displaying said contents on said edit screen for said child project when said child project is selected from said edit screen displayed for said parent project on said display means; and
second editing means for enabling contents of said child project to be edited by displaying setup information relating thereto on a new edit screen when said contents of said child project are selected from said edit screen displayed for said child project on said display means.

10. A test apparatus for a control unit, comprising:
testing means for testing the operation of said control unit based on a relationship between a pattern signal input to said control unit and an output signal output in response to said pattern signal from a target being controlled by said control unit; and
means for causing said testing means during execution of said pattern signal to switch to the execution of another pattern signal when a pattern signal transition condition for making a transition to the execution of said other signal holds.

11. A test method for testing the operation of a control unit, comprising:
a simulating step for simulating a target to be controlled by said control unit; and
a testing step for testing the operation of said control unit based on a relationship between a pattern signal input to said control unit and an output signal output in said simulating step in response to said pattern signal, wherein
said testing step tests the operation of said control unit at predetermined timing and, if a decision is not obtained that said control unit is operating properly, retries said decision a predetermined number of times.

12. A pattern signal creating method for creating a pattern signal, comprising:
a first function processing step for creating said pattern signal based on a control interval at which to control a unit that uses said pattern signal; and
a second function processing step for creating said pattern signal based on an interval different from said control interval.

13. A pattern signal creating method as claimed in claim 12, wherein said second function processing step creates said pattern signal based on an interval of time that extends over a plurality of said control intervals.

14. A pattern signal creating method as claimed in claim 13, wherein said second function processing step creates said pattern signal based on an interval equal to each of said control intervals.

15. A pattern signal creating method for creating a pattern signal, comprising:
a step for creating a reference pattern signal;
a step for creating a correlation pattern signal for which correlation information relative to said reference pattern signal is specified; and
a displaying step for displaying said reference pattern signal and said created correlation pattern signal on the same screen.

16. A pattern signal creating method for creating a pattern signal, comprising:
a displaying step for displaying, when there exists a correlation pattern signal for which correlation information relative to a reference pattern signal is specified, said reference signal and said correlation pattern signal on the same screen;
a pattern signal interlinking changing step for changing said correlation pattern signal in interlinking fashion as said reference pattern signal changes; and
a step for redisplaying, when said reference pattern signal is edited, said correlation pattern signal changed in said pattern signal interlinking changing step along with said edited reference pattern signal.

17. A test program creating method for creating a test program for testing a diagnostic function by causing a control unit to output data, comprising:
a step for displaying said pattern signal to be processed in said control unit onto a screen; and
a step for enabling a setting to be made for said testing of said diagnostic function.

18. A test program creating method as claimed in claim 17, wherein said setting for said testing of said diagnostic function involves setting data output request information to be transmitted to said control unit and also setting a condition based on which to determine whether said diagnostic function is working properly or not when said data output request information is transmitted to said control unit.

19. A test program creating method for creating a test program comprising a child project which contains a pattern signal to be input to a control unit and a condition for effecting a transition from said pattern signal to another pattern signal and a parent project which contains said child project and a condition for effecting a transition from said child project to another child project, said method comprising;
a displaying step for simultaneously displaying an edit screen for said child project and an edit screen for said parent project;
a first editing step for enabling contents of said child project to be edited by displaying said contents on said edit screen for said child project when said child project is selected from said edit screen displayed for said parent project in said displaying step; and
a second editing step for enabling contents of said child project to be edited by displaying setup information relating thereto on a new edit screen when said contents of said child project are selected from said edit screen displayed for said child project in said displaying step.

20. A test method for testing the operation of a control unit based on a relationship between a pattern signal input to said control unit and an output signal output in response to said pattern signal from a target being controlled by said control unit, said method comprising;
a step for executing said pattern signal; and
a step for switching, during execution of said pattern signal, to the execution of another pattern signal when a pattern signal transition condition for making a transition to the execution of said other signal holds.
